(19) United States
(12) Patent Application Publication
(10) Pub. No.: US 2022/0068758 A1
(43) Pub. Date: Mar. 3, 2022

(54) RADIATION BOARD

(71) Applicant: THE GOODSYSTEM CORP., Ansan-si (KR)

(72) Inventors: Meoung-whan CHO, Yongin-si (KR); Seog-woo LEE, Hwaseong-si (KR); Young-suk KIM, Suwon-si (KR)

(21) Appl. No.: 17/422,878

(22) PCT Filed: Jan. 13, 2020
(86) PCT No.: PCT/KR2020/000560

§ 371 Date: Jul. 14, 2021

(30) Foreign Application Priority Data
Jan. 15, 2019 (KR) 10-2019-0005078

(51) Int. Cl. H01L 23/373

(52) U.S. Cl. CPC H01L 23/3735; H01L 23/3736

(57) ABSTRACT

The objective of the present invention is to provide a radiation board, which has a low thermal expansion coefficient so as to prevent bending or damage caused by a difference in thermal deformation during bonding to a ceramic material (particularly, alumina), has high thermal conductivity in the thickness direction of the board so as to be applicable to a chip of a high power element such as a power transistor having hundreds of watts, and prevents a problem, such as a finishing defect, during a plating process performed while an electronic element is mounted.

The radiation board according to the present invention comprises: a core layer having metal and nonmetal materials; a first cover layer for covering upper and lower surfaces of the core layer; and a second cover layer for covering at least some side surfaces of the core layer, wherein the first cover layer and the second cover layer are made of a material that can be plated on externally exposed surfaces thereof.

### TECHNICAL FIELD

The present invention relates to a radiation board, and more particularly, to a radiation board that is capable of being suitably used for packaging of a high power semiconductor element using a compound semiconductor. The radiation board has a thermal expansion coefficient that is equal or similar to that of a ceramic material so that the radiation board is satisfactorily bonded even when the radiation board is bonded to an element made of the ceramic material such as alumina (Al₂O₃), and simultaneously, the radiation board has high thermal conductivity capable of rapidly radiating a large amount of heat generated in the high power element to the outside.

### BACKGROUND ART

Recently, a high power amplification element using a GaN-based compound semiconductor is attracting attention as a core technology in the fields of information communication and national defense.

In such a high power electronic element or optical element, a large amount of heat is generated compared to a general element, and a packaging technology capable of efficiently radiating the large amount of heat generated as described above is required.

Currently, a high power semiconductor element using a GaN-based compound semiconductor uses a metal-based composite board having relatively good thermal conductivity and a low thermal expansion coefficient such as a two-layered composite of tungsten (W)/copper (Cu), a two-phase composite of copper (Cu) and molybdenum (Mo), a three-layered composite of copper (Cu)/copper-molybdenum (Cu—Mo) alloy/copper (Cu), and a multi-layered composite of copper (Cu)/molybdenum (Mo)/copper (Cu)/molybdenum (Mo)/copper (Cu).

However, since thermal conductivity of each of the composite boards in a thickness direction is about 200 W/mK to about 300 W/mK. Since the composite boards do not actually implement thermal conductivity beyond the above-described thermal conductivity, a new radiation material or radiation board to be applied for hundreds of watt-class power transistors are urgently required.

In the process of manufacturing a semiconductor element, a brazing bonding process with a ceramic material such as alumina (Al₂O₃) is essential.

Since this brazing bonding process is performed at a high temperature of about 800° C. or more, bending or damage occurs in the brazing bonding process due to a difference in thermal expansion coefficient between the metal composite board and the ceramic material. As a result, the bending or damage has a fatal effect on reliability of the element.

Furthermore, in recent years, in order to implement high power and improve production efficiency during the manufacturing, several chips are mounted on a single radiation board to increase in length of a package. As described above, when the length of the package increases, a length of the radiation board also becomes longer. Thus, even if the difference in thermal expansion coefficient between the radiation board and the semiconductor element, which does not have the problem when mounting the single chip, there is a problem when the number of mounted semiconductor elements increases. Therefore, in the case of the radiation board used to mount several chips, similarity of the thermal expansion coefficient of the ceramic material becomes more important. Thus, there is a demand for the development of a radiation board having high similarity with the thermal expansion coefficient of the ceramic material when compared to the related art and superior radiation characteristics.

In order to respond to this demand, the present inventors has disclosed a radiation board constituted by cover layers (first layer and fifth layer) made of copper (Cu), intermediate layers (second layer and fourth layer) made of an alloy of copper (Cu) and molybdenum (Mo), and a core layer having a structure in which copper (Cu) and molybdenum (Mo) are alternately disposed in a direction parallel to top and bottom surfaces of the radiation board, as disclosed in Korean Patent Laid-Open No. 2018-0097021. The radiation board having the above-described structure has superior thermal conductivity while being similar to the thermal expansion coefficient of the ceramic material, but there is a problem that delamination occurs by an unstable bonding surface between the core layer and each of the intermediate layers at a high temperature.

In the case of the radiation board to which a composite using metal and non-metal materials is applied, a plating process (for example, a process such as Ni—Au electrolytic plating) of mounting the element on the radiation board is required. Here, a blister phenomenon due to the plating process occurs to cause a poor outer appearance and have a fatal adverse effect on reliability of the radiation board.

### DISCLOSURE OF THE INVENTION

### Technical Problem

The present invention is for solving the problems of the prior art, and an object of the present invention is to provide a radiation board, which has a low thermal expansion coefficient so as to prevent bending or damage caused by a difference in thermal deformation during bonding to a ceramic material (particularly, alumina), has high thermal conductivity in the thickness direction of the board so as to be applicable to a chip of a high power element such as a power transistor having hundreds of watts, and prevents a problem, such as a blister defect due to a plating process performed while an electronic element is mounted.

### Technical Solution

The present invention for achieving the above object provides a radiation board including a core layer having metal and nonmetal materials, a first cover layer covering top and bottom surfaces of the core layer, and a second cover layer covering at least a portion of a side surface of the core layer, wherein each of the first cover layer and the second cover layer is made of a material that of which an externally exposed surface is capable of being plated.

### Advantageous Effects

In the radiation board according to the present invention, the core layer including the metal and non-metal materials may be made of the metal and be covered by the cover layer having the predetermined thickness, so that the outer appearance defects such as the blister defect in the plating process performed in the process of mounting the electronic element may not occur.

In addition, the radiation board according to an embodiment of the present invention may have excellent interlayer bonding strength constituting each layer, and may maintain excellent bonding strength even when used at high temperature for a long time.

In addition, the radiation board according to an embodiment of the present invention has the high thermal conductivity of 400 W/mK or more in the thickness direction of the board without using the expensive material such as diamond or tungsten (W) to economically manufacture the radiation board for the high power element.

In addition, the radiation board according to an embodiment of the present invention may maintain the thermal expansion coefficient of 8.0×10⁻⁶/K to 9.0×10⁻⁶/K in the plane direction in which the first layer and the second layer are alternately disposed to prevent the bending or the delamination or the damage of the ceramic material during the brazing process because the difference in thermal expansion coefficient between the radiation board and the high power element made of the ceramic material to be brazing-bonded to the radiation board is not large.

### BRIEF DESCRIPTION OF THE DRAWINGS

FIG. 1 is view for explaining a thickness direction and a plane direction of a radiation board.

FIG. 2 is a perspective view of the radiation board according to an embodiment of the present invention.

FIG. 3 is a cross-sectional view taken along line A-A of FIG. 2.

FIG. 4 is a schematic view of a core layer in the radiation board according to an embodiment of the present invention.

FIG. 5 is a schematic view of a core layer having a different shape in the radiation board.

FIG. 6 is an image obtained by photographing a cross-section, which is taken along line A-A, of the radiation board manufactured according to an embodiment of the present invention.

FIG. 7 is an image obtained by observing a portion of a core layer by using a scanning electron microscope on the cross-section, which is taken along line A-A, of the radiation board manufactured according to an embodiment of the present invention.

FIG. 8 is a view illustrating a state of an outer appearance after Ni—Au electroplating of the radiation board on which a second cover layer is not formed or which is formed at a predetermined thickness or less.

FIG. 9 is a view illustrating a state of an outer appearance after Ni—Au electroplating of the radiation board, on which the second cover layer is formed, according to an embodiment of the present invention.

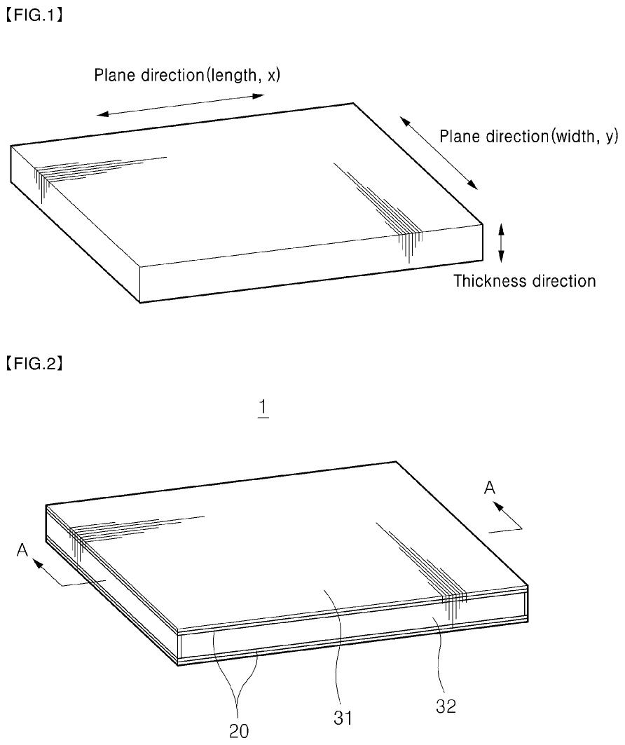

### MODE FOR CARRYING OUT THE INVENTION

Hereinafter, preferred embodiments of the present invention will be described below in more detail with reference to the accompanying drawings. Following embodiments of the present invention may, however, be embodied in different forms and should not be constructed as limited to the foregoing embodiments set forth herein. Rather, the embodiments of the present invention are provided so that this disclosure will be thorough and complete, and will fully convey the scope of the present invention to those skilled in the art.

The present inventor may find that a radiation board having a following structure is capable of achieving the above effects to lead to the present invention through studies for implementing a radiation board, which has excellent bonding strength between each of layers constituting the radiation board, is capable of implementing high thermal conductivity in a thickness direction of the board, and does not cause an outer appearance defects during plating performed in a process of mounting an electronic element.

The radiation board according to the present invention includes a core layer having metal and nonmetal materials, a first cover layer covering top and bottom surfaces of the core layer, and a second cover layer covering at least a portion of a side surface of the core layer, wherein each of the first cover layer and the second cover layer is made of a material of which an externally exposed surface is capable of being plated.

In addition, one or more intermediate layers may be additionally included between the top and bottom surfaces of the core layer and the first cover layer.

In addition, the core layer may have a structure, in which the first layer made of a metal and the second layer made of a composite of metal and non-metal materials are alternately arranged in a direction parallel to or perpendicular to the top and bottom surfaces of the radiation board. In the case of the alternately arranged structure, in order to maintain a low thermal expansion coefficient in a plane direction of the radiation board and also high thermal conductivity in a thickness direction of the radiation board, it is more preferable to provide the structure in which the first layer and the second layer are alternately arranged in the direction (i.e., a plane direction) parallel to the top and bottom surfaces of the radiation board.

In addition, each of the first cover layer and the second cover layer, preferably, may be made of copper or a copper alloy. In the case of the copper alloy, various alloy elements may be included, and in consideration of radiation characteristics, it is more preferable to include copper in amount of 80% by weight or more.

In addition, in consideration of the increase in bonding strength between the core layer and the first cover layer, the thermal expansion coefficient required for the radiation board, and the radiation performance (that is, thermal conductivity) required for the radiation board, the intermediate layer may be formed as a single layer (one layer) or multilayer structure, preferably, a single layer made of an alloy of copper and molybdenum. Here, the alloy of copper and molybdenum may preferably contain 30% to 60% by weight of copper (Cu) and 40% to 70% by weight of molybdenum (Mo). This is done because, if the content of copper (Cu) is less than 30% by weight, the thermal expansion coefficient is too small to 7×10⁻⁶/K or less to cause bending in a direction of ceramic when being brazing-bonded to ceramic, and if the content of copper (Cu) exceeds 60% by weight, the thermal expansion coefficient is too large to 9×10⁻⁶/K or more to cause bending in a direction that is opposite to ceramic.

In addition, the first layer constituting the core layer, preferably, may be made of copper or a copper alloy, like the first cover layer and the second cover layer. In this case, when the first layer is made of the copper alloy, various alloy elements may be included in the same manner as in the first cover layer and the second cover layer. The second layer constituting the core layer may be made of a composite in which copper or a copper alloy is used as a matrix, and a non-metal material made of carbon is dispersed in the matrix.

In addition, the composite of the second layer, preferably, may be made of copper and graphite particles. The graphite particles having a structure, in which a direction of a plane (direction parallel to a plane) having a relatively large area is substantially oriented in parallel the thickness direction of the radiation board is preferable in the aspect of improving the thermal conductivity in the thickness direction of the radiation board.

In addition, in the composite of the second layer, a ratio of copper and graphite may be variously adjusted according to required characteristics, and a volume fraction of graphite particles occupied in the composite may be 10% to 90%, preferably, 20% to 80%, more preferably 30% to 70%.

In addition, the graphite particles may preferably have a shape such as a board shape, a flake shape, a scale shape, or a needle shape. Here, ‘the structure oriented in parallel to the thickness direction’ refers to a structure in which an area fraction occupied by particles having an internal angle of less than 45° between the thickness direction of the radiation board and the plane direction of the graphite particles exceeds 50% of an area of the total graphite particles, preferably, 70% or more. The thermal conductivity in the thickness direction of the radiation board may increase, and simultaneously, the lower thermal expansion coefficient in the plane direction may be maintained through the composite structure of the second layer,

In addition, the first layer and the second layer are preferably directly bonded to the first cover layer or directly bonded to the intermediate layer when the intermediate layer is disposed between the first cover layer and the core layer in terms of improving the bonding strength.

In addition, when the thickness of the intermediate layer is less than 5% of the total thickness of the radiation board, it may be difficult to maintain the thermal expansion coefficient at 8.0×10⁻⁶/K to 9.0×10⁻⁶/K, and when the thickness exceeds 20% of the total thickness of the radiation board, since it is difficult to maintain the thermal conductivity in the thickness direction of the radiation board at 400 W/mK or more, it is preferable to maintain the thickness of the intermediate layer at 5% to 20% of the total thickness of the radiation board.

In addition, when the thickness of the first cover layer is less than 5% of the total thickness of the radiation board, the thermal expansion coefficient is too low to cause bending or poor radiation characteristics. When the thickness of the first cover layer exceeds 40% of the total thickness of the radiation board, the thermal expansion coefficient is too high to cause bending in the opposite direction. Thus, it is preferable that the thickness of the first cover layer is 5% to 40% of the total thickness of the radiation board, and upper and lower layers have the same thickness.

In addition, when the thickness of the second cover layer formed on the plane that is in contact with the second layer constituting the core layer is 8 μm or less, a blister occurs during the plating process performed to mount the electronic element on the radiation board to cause the outer appearance defects. Thus, it is preferable that the thickness of the second cover layer is more than 8 μm, more preferable, 10 μm or more.

In addition, when the thickness of the second cover layer is excessively formed, the thermal expansion coefficient of the radiation board may increase, and thus, it is preferable that the thickness of the second cover layer is more than 8 μm to 3 mm or less.

In addition, in the radiation board according to an embodiment of the present invention, the thermal expansion coefficient in the direction in which the first layer and the second layer are alternately repeated is implemented at a level of 7.0×10⁻⁶/K to 9.0×10⁻⁶/K.

In addition, in the radiation board according to an embodiment of the present invention, the thermal conductivity in the thickness direction is implemented at 400 W/mK or more.

### Embodiment

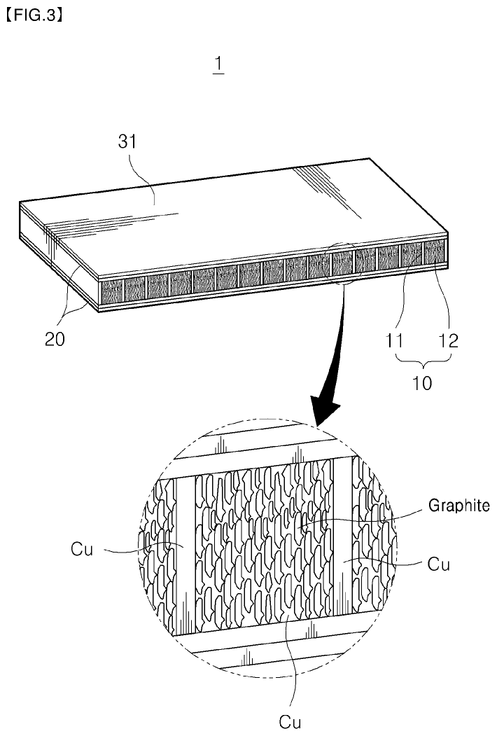

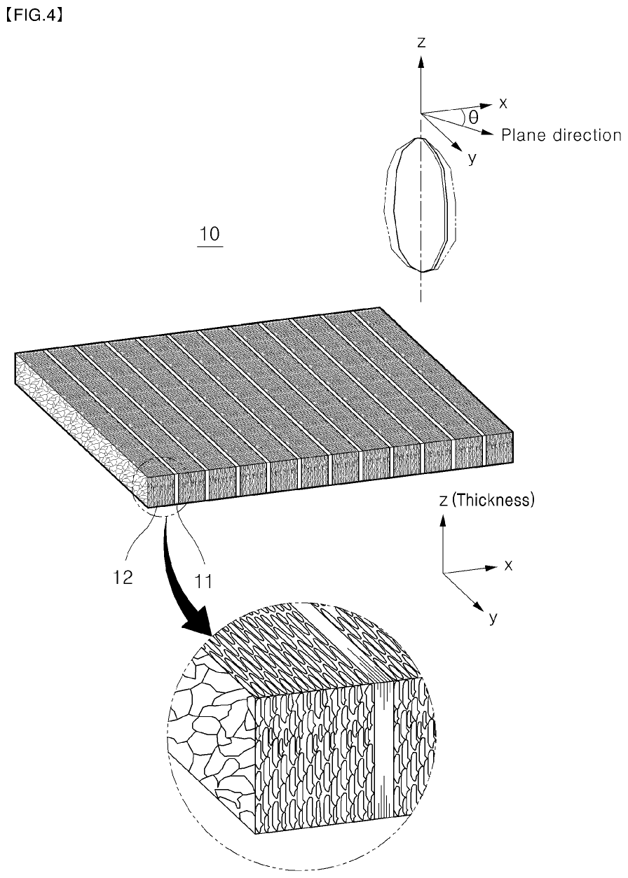

FIG. 2 is a perspective view of the radiation board according to an embodiment of the present invention, FIG. 3 is a cross-sectional view taken along line A-A of FIG. 2, and FIG. 4 is a schematic view of the core layer in the radiation board according to an embodiment of the present invention.

As illustrated in FIGS. 2 to 4, a radiation board 1 according to an embodiment of the present invention includes a core layer 10 including metal and non-metal materials, an intermediate layer 20 formed on each of top and bottom surfaces of the core layer 10, a first cover layer 31 covering each of the top and bottom surfaces of the intermediate layer 20, and a second cover layer 32 covering a side surface of the core layer 10.

Among them, each of the first cover layer 31 and the second cover layer 32 is made of copper (Cu) containing 99% or more of copper (Cu), and the intermediate layer 20 is a copper-molybdenum (Cu—Mo) alloy (Cu: 45% by weight and Mo: 55% by weight).

When viewed in a plane view, the core layer 10 has a structure, in which a first layer 11 made of copper (Cu) and a second layer 12 made of a copper (Cu)-graphite (flaky graphite) composite are alternately repeatedly arranged in a longitudinal direction (x-direction) of the radiation board. In addition, the first layer 11 and the second layer 12 are formed to be in direct contact with the copper-molybdenum (Cu—Mo) alloy layer, which is the intermediate layer 20, in the thickness direction.

The above-described structure may reduce the thermal expansion coefficient in the longitudinal direction (x-direction) of the radiation board and also maximally maintain the thermal conductivity in the thickness direction, and simultaneously, may improve bonding strength between the core layer 10, the intermediate layer 20, and the first cover layer 31 to prevent the layers from being delaminated from each other.

In addition, as illustrated in FIG. 4, the copper (Cu)-graphite composite layer constituting the second layer 12 may be maintained in a state in which a direction parallel to the plane of the board-shaped graphite particles (that is, the plane direction) is oriented to be in parallel to the thickness direction of the radiation board. When the graphite particles having excellent thermal conductivity are oriented as described above, the thermal conductivity in the thickness direction of the radiation board may be further improved.

In FIG. 4, a thickness of the flake shape is shown in an x-direction, and a plane of the flake shape is shown in a y-direction, but as illustrated at a right side of FIG. 4, an internal angle θ between the direction parallel to the plane of the graphite particles, which is shown on the cross-section of the second layer 12, and an x-axis may vary. That is, it is sufficient that the direction of the plane of the graphite particles is oriented more than a certain degree in the thickness direction, and the shape expressed in the x and y cross-sections is not substantially affected.

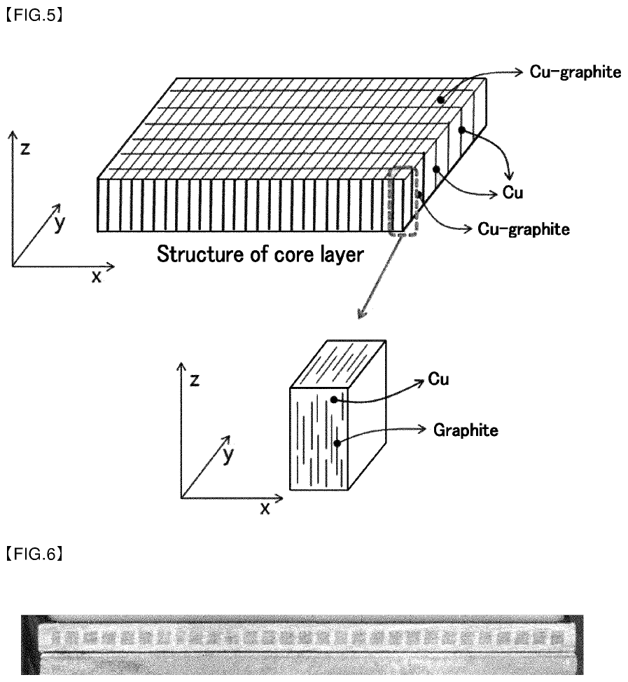

In addition, in the embodiment of the present invention, the first layer 11 and the second layer 12 are alternately repeatedly formed in the longitudinal direction (x-direction) of the radiation board, and as illustrated in FIG. 5, a first layer 11′ and a second layer 12′ may be alternately repeatedly formed in a width direction (y-direction) as well as in the longitudinal direction (x-direction) to form a checkerboard arrangement. In this case, thermal expansion coefficient in the width direction may also be implemented similarly to the longitudinal direction.

The radiation board having the above structure was manufactured through following processes.

First, a copper (Cu) board having a thickness of about 200 μm, a length of 100 mm, and a width of 100 mm was prepared as a first cover layer, and a copper-molybdenum (Cu—Mo) alloy board (Cu: 60% by weight-Mo: 40% by weight) having a thickness of about 50 μm, a length of 100 mm, and a width of 100 mm was prepared as an intermediate layer.

Next, the core layer was prepared so that a copper board having a thickness of about 50 μm and a copper (Cu)-graphite composite board having a thickness of about 600 μm, which is prepared by sintering copper-graphite powder that is thinly coated with copper on flake-shaped graphite, is laminated to be bonded in a press sintering manner, and the bonded bulk material is cut in a direction perpendicular to a lamination direction of the materials by using various cutting manners to prepare a board on which a copper (Cu) layer (first layer) having a thickness of about 700 μm and copper (Cu)-graphite layers (second layer) are alternately disposed.

Thereafter, the intermediate layer was disposed on each of top and bottom surfaces of the prepared core layer, and a first cover layer was disposed on a surface of the intermediate layer and then bonded in the press sintering manner.

In addition, a copper (Cu) board having a thickness of about 300 μm was laminated on a side surface of the core layer and then bonded in the press sintering manner to form a second cover layer so that the surface of the core layer is covered by copper (Cu).

In an embodiment of the present invention, the second cover layer was formed to cover the surface of the core layer, on which graphite is exposed, in order to secure a predetermined level of the thermal expansion coefficient, but according to the level of the required thermal expansion coefficient, the second cover layer may cover the intermediate layer as well as the core layer as well or cover the entire side surface of the core layer regardless of the exposure of graphite.

As described above, in an embodiment of the present invention, each board was prepared and then bonded using the press sintering manner, but it is needless to say that the laminated structure according to the present invention may be implemented by various methods such as plating and vapor deposition.

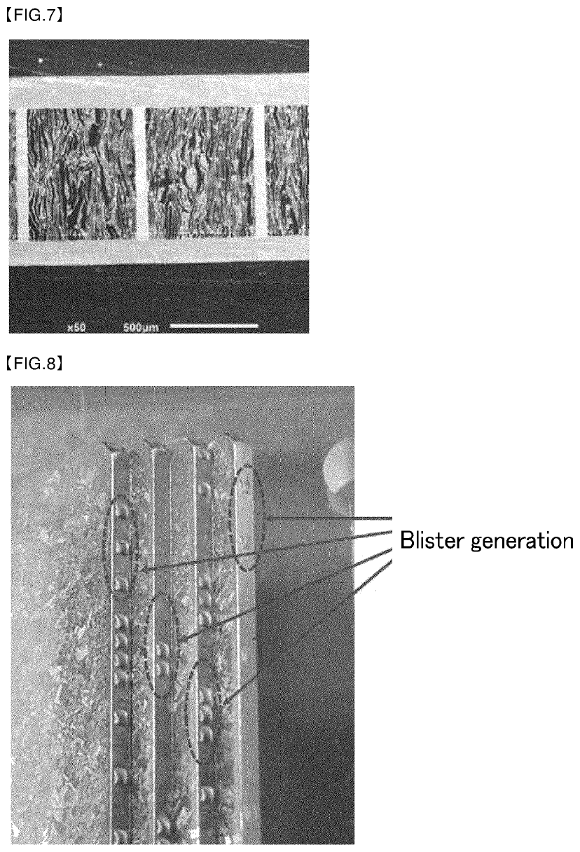

FIG. 6 is an image obtained by photographing a cross-section, which is taken along line A-A, of the radiation board manufactured according to an embodiment of the present invention, and FIG. 7 is an image obtained by observing a portion of a core layer by using a scanning electron microscope on the cross-section, which is taken along line A-A, of the radiation board manufactured according to an embodiment of the present invention.

As illustrated in FIGS. 6 and 7, in the radiation board manufactured through the above process, an outer surface is constituted by a first cover layer and a second cover layer, each of which is made of copper (Cu), and the inside thereof has a configuration, in which a core layer having a structure, a first layer made of copper (Cu) and a second layer made of a copper (Cu)-graphite composite are alternately repeatedly arranged in a longitudinal direction, is disposed at a center, a copper-molybdenum (Cu—Mo) layer is formed on each of top and bottom surfaces of the core layer, and the first cover layer made of copper (Cu) is formed on a surface of the copper-molybdenum (Cu—Mo) layer. In addition, as illustrated in FIG. 7, in the case of the second layer made of the copper (Cu)-graphite composite, the graphite particles have a structure in which the graphite particles are oriented in the thickness direction of the radiation board.

Table 1 below shows results obtained by measuring a thermal expansion coefficient in the plane direction (x-direction) of the radiation board and thermal conductivity (an average value of results measured by selecting 10 random places on the radiation board) according to an embodiment of the present invention, and results obtained by measuring thermal conductivity and thermal expansion coefficient of a copper board under the same conditions according to Comparative Example.

TABLE 1

| | | Thermal | |
|---|---|---|---|
| | Thermal | expansion | |
| | conductivity | coefficient in | |
| | in | longitudinal | |
| | thickness | direction at | |
| | direction | 800° C. | |
| Classification | (W/mK) | (×10⁻⁶/K) | Blister |
| Embodiment | 430 | 8.26 | None |
| Comparative | 380 | 17 | None |
| Example 1 (copper | | | |
| board) | | | |

As shown in Table 1, the thermal expansion coefficient of the radiation board according to an embodiment of the present invention represents a thermal expansion coefficient of 8.26×10⁻⁶/K in the plane direction, and this value is not different from the thermal expansion coefficient of ceramic forming a high power semiconductor element, and thus, there is no problem of bending or delamination when the high power semiconductor element is mounted.

In addition, the thermal conductivity in the thickness direction of the radiation board according to an embodiment of the present invention corresponds to a level exceeding 400 W/mK, which is not only superior to the board made of only copper (Comparative Example 1), but also has a higher level of a radiation characteristic than that of any radiation board, which is capable of implementing a thermal expansion coefficient of 9×10⁻⁶/K or less.

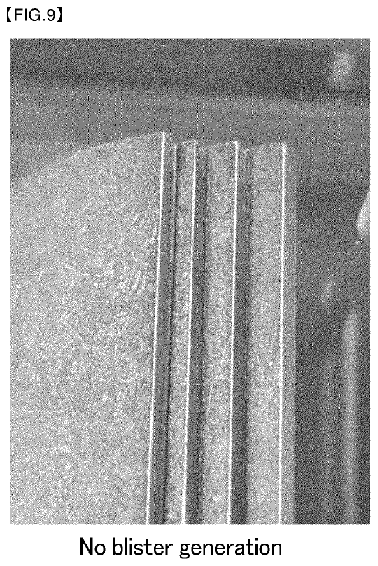

FIG. 8 is a view illustrating a state of an outer appearance after Ni—Au electroplating of the radiation board on which a second cover layer is not formed or which is formed at a predetermined thickness or less, and FIG. 9 is a view illustrating a state of an outer appearance after Ni—Au electroplating of the radiation board, on which the second cover layer is formed, according to an embodiment of the present invention.

As illustrated in FIG. 8, in case of a radiation board having the same structure as the embodiment of the present invention without forming only the second cover layer or when formed to a predetermined thickness or less, a plurality of blisters are generated along the side surface of the core layer during the Ni—Au electroplating to deteriorate quality of the outer appearance. In contrast, as illustrated in FIG. 9, in the case of the radiation board according to an embodiment of the present invention, blisters were not generated even after the nickel-gold (Ni—Au) electroplating.

Table 2 below shows results obtained by analyzing whether the blisters are generated during the nickel-gold (Ni—Au) electroplating depending on the thickness of the second cover layer in the radiation board according to an embodiment of the present invention.

TABLE 2

| Thickness of second | Whether to |
|---|---|
| cover layer | generate |
| (μm) | side blister |
| 1 | ◯ |
| 3 | ◯ |
| 5 | ◯ |
| 8 | ◯ |
| 10 | X |
| 30 | X |
| 100 | X |
| 300 | X |
| 500 | X |
| 1000 | X |
| 2500 | X |
| 3000 | X |

◯: When blister is observed
X: When blister is not observed

As shown in Table 2 above, when the thickness of the second cover layer made of Cu, which is formed on a surface the side surface of the core layer, which is in contact with graphite, is less than 9 μm, if the nickel-gold (Ni—Au) electroplating is performed on the radiation board, the blisters are generated. However, when the thickness of the cover layer is 9 μm or more (preferably, 10 μm or more), the blisters are not substantially generated.

Since the results in Table 2 are for the case of performing the nickel-gold (Ni—Au) plating with the second cover layer made of Cu, it should be understood that the thickness of the second cover layer also varies to prevent the blisters from being generated according to a difference in plating process.

In addition, in the radiation board according to an embodiment of the present invention, the delamination phenomenon between the layers did not occur at a high temperature.

1. A radiation board comprising:
a core layer comprising metal and nonmetal materials;
a first cover layer configured to cover each of top and bottom surfaces of the core layer; and
a second cover layer configured to cover at least a portion of a side surface of the core layer, wherein each of the first cover layer and the second cover layer is made of a material of which an external exposed surface is capable of being plated.

2. The radiation board of claim 1, wherein one or more intermediate layer is additionally disposed between each of the top and bottom surfaces of the core layer and the first cover layer.

3. The radiation board of claim 1, wherein the core layer has a structure, in which a first layer made of the metal and a second layer made of a composite of the metal and non-metal materials are alternately repeated in a direction parallel to the top and bottom surfaces of the radiation board.

4. The radiation board of claim 1, wherein the core layer has a structure, in which a first layer made of the metal and a second layer made of a composite of the metal and non-metal materials are alternately repeated in a direction perpendicular to the top and bottom surfaces of the radiation board.

5. The radiation board of claim 3, wherein each of the first cover layer and the second cover layer is made of copper or a copper alloy.

6. The radiation board of claim 3, wherein the first layer is made of copper or a copper alloy, and
the second layer is made of a composite in which the copper or the copper alloy is used as a matrix, and the non-metal material made of carbon is dispersed in the matrix.

7. The radiation board of claim 2, wherein the intermediate layer is provided as a single layer and made of a copper-molybdenum alloy.

8. The radiation board of claim 6, wherein the non-metal material made of carbon is graphite.

9. The radiation board of claim 3, further comprising an intermediate layer made of an alloy of copper and molybdenum between each of the top and bottom surfaces of the core layer and the cover layer.

10. The radiation board of claim 3, wherein each of the first layer and the second layer is directly bonded to the first cover layer.

11. The radiation board of claim 2, wherein the core layer has a structure, in which a first layer made of the metal and a second layer made of a composite of the metal and non-metal materials are alternately repeated in a direction parallel to the top and bottom surfaces of the radiation board, and
each of the first layer and the second layer is directly bonded to the intermediate layer.

12. The radiation board of claim 8, wherein a second cover layer formed on a surface that is in contact with the second layer has a thickness of 9 μm.

13. The radiation board of claim 10, wherein the non-metal material comprises graphite particles and has a structure, in which a direction parallel to a plane of each of the graphite particles, which has a relatively large area, (a plane direction) is oriented to be in parallel to a thickness direction of the radiation board.

14. The radiation board of claim 4, wherein each of the first cover layer and the second cover layer is made of copper or a copper alloy.

15. The radiation board of claim 4, wherein the first layer is made of copper or a copper alloy, and
the second layer is made of a composite in which the copper or the copper alloy is used as a matrix, and the non-metal material made of carbon is dispersed in the matrix.

16. The radiation board of claim 4, further comprising an intermediate layer made of an alloy of copper and molybdenum between each of the top and bottom surfaces of the core layer and the cover layer.

17. The radiation board of claim 11, wherein the non-metal material comprises graphite particles and has a structure, in which a direction parallel to a plane of each of the graphite particles, which has a relatively large area, (a plane direction) is oriented to be in parallel to a thickness direction of the radiation board.
